(19) United States
(12) Patent Application Publication
(10) Pub. No.: US 2014/0119493 A1
(43) Pub. Date: May 1, 2014

(54) SHIFT REGISTER AND GATE DRIVING DEVICE ON ARRAY SUBSTRATE

(71) Applicants: BOE TECHNOLOGY GROUP CO., LTD., Beijing (CN); HEFEI BOE OPTOELECTRONICS TECHNOLOGY CO., LTD., Beijing (CN)

(72) Inventors: Tong YANG, Beijing (CN); Rui MA, Beijing (CN); Ming HU, Beijing (CN)

(73) Assignees: BOE TECHNOLOGY GROUP CO., LTD., Beijing (CN); HEFEI BOE OPTOELECTRONICS TECHNOLOGY CO., LTD., Beijing (CN)

(21) Appl. No.: 14/067,072

(22) Filed: Oct. 30, 2013

(30) Foreign Application Priority Data
Oct. 30, 2012 (CN) 201210424448.7

(51) Int. Cl. G11C 19/28

(52) U.S. Cl. CPC G11C 19/28
USPC 377/64

(57) ABSTRACT

Provided are a shift register and a gate driving device on array substrate for eliminating noise at an output terminal of the shift register and improving the operating stability thereof. The shift register comprises an input module for supplying an input signal to a pull-up node, wherein the pull-up node serves as an output node of the input module; a pull-up module for storing the input signal and supplies a first clock signal to the output terminal; a reset module for supplying a negative voltage of a power supply to the pull-up node; a first pull-down control module for supplying the negative voltage to a first pull-down node; a second pull-down control module for supplying the negative voltage to a second pull-down node; and a pull-down module for supplying the negative voltage to the pull-up node, and for supplying the negative voltage to the output terminal.

### TECHNICAL FIELD

The present disclosure relates to the art of driving technique for liquid crystal display and particularly to a shift register and a gate driving device on array substrate including the shift register.

### BACKGROUND

A flat panel display has been popularized due to its super-thin in thickness and energy-saving characteristics. Most of the flat panel displays utilize a shift register, wherein the shift register is implemented by integrating a gate driving device into a liquid crystal panel, i.e., Gate-driver On Array (GOA), so that a gate driving IC can be omitted and one manufacturing process can be reduced, and thus the cost for manufacturing the flat panel display can be decreased and the production period is shorten to some extent. Therefore, recently the GOA technique has been widely used in manufacturing of the flat panel display. The lifespan of the GOA and its stability in output have been gained more attention in design of GOA.

FIG. 1 shows a most basic unit in GOA which comprises four thin film transistors and a capacitor. In a practical application, the transistor T2 in the GOA unit is affected by a coupling voltage generated by a clock signal at a first clock signal terminal CLK, so that noise appears in an output terminal OUTPUT, and thus the GOA unit cannot operate stably for a long time. At present, though many patents on GOA provide some solutions for addressing the above problems and can solve the same substantially, there is no solution for GOA to address the issue concerning noise in the output terminal and bad stability thoroughly.

### SUMMARY

In embodiments of the present disclosure, there are provided a shift register and a gate driving device on an array substrate for eliminating the noise at the output terminal of the shift register and improving the operating stability of the shift register.

According to one aspect of the present disclosure, in an embodiment of the present disclosure, there is provided a shift register, comprising an input module, a pull-up module, a reset module, a first pull-down control module, a second pull-down control module and a pull-down module;

wherein the input module supplies an input signal to a pull-up node in responsive to the input signal, wherein the pull-up node serves as an output node of the input module;

the pull-up module stores the input signal and supplies a first clock signal to an output terminal in responsive to a voltage signal at the pull-up node;

the reset module supplies a negative voltage at a negative voltage terminal of a power supply to the pull-up node in responsive to a reset signal;

the first pull-down control module supplies the negative voltage of the power supply to a first pull-down node in response to the voltage signal at the pull-up node;

the second pull-down control module supplies the negative voltage of the power supply to a second pull-down node in response to the input signal; and

the pull-down module supplies the negative voltage of the power supply to the pull-up node in responsive to voltage signals at the first pull-down node and the second pull-down node, and supplies the negative voltage of the power supply to the output terminal in responsive to the voltage signals at the first pull-down node and the second pull-down node.

According to another aspect of the present disclosure, in an embodiment of the present disclosure, there is provided a gate driving device on an array substrate comprising a plurality of the shift registers connected in concatenation.

In the shift register, the driving method for the same, and the gate driving device on the array substrate, the issue of the noise occurring at the output terminal of the shift register is thoroughly addressed, and the operating stability of the shift register can be improved.

### BRIEF DESCRIPTION OF THE DRAWINGS

FIG. 1 is a schematic diagram showing a structure of a shift register as the most basic unit in GOA in prior art;

FIG. 2 is a schematic diagram showing a structure of a shift register provided in an embodiment of the present disclosure;

FIG. 3 is a timing diagram showing control signals in the shift register provided in an embodiment of the present disclosure;

FIG. 4 is a schematic diagram showing a structure of another shift register provided in an embodiment of the present disclosure;

FIG. 5 is a timing diagram of signals in the shift register shown in FIG. 4 when the shift register operates in the process for driving; and

FIG. 6 is a schematic diagram showing a structure of a gate driving device on an array substrate.

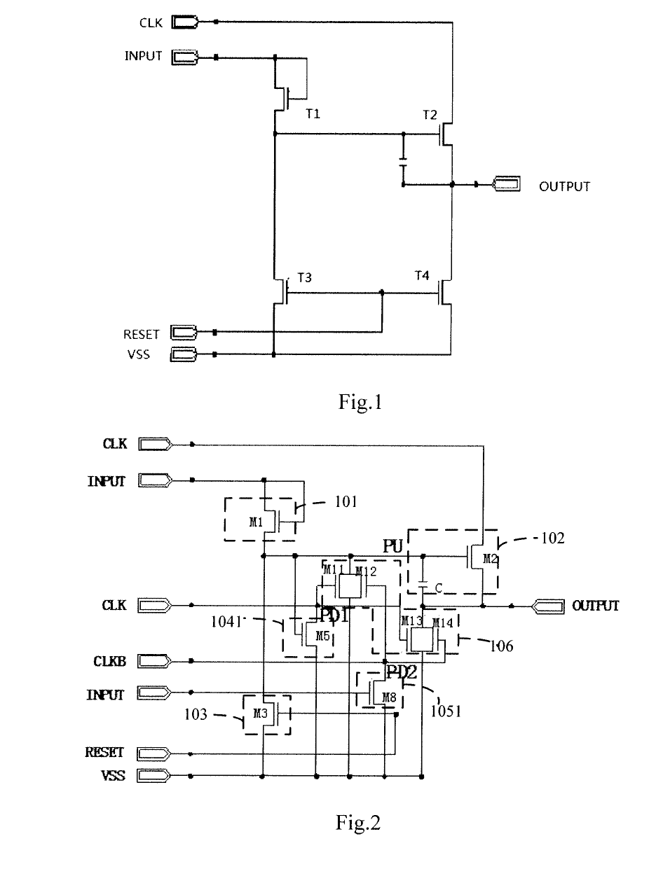

### DETAILED DESCRIPTION OF THE PREFERRED EMBODIMENTS

In embodiments of the present disclosure, provided are a shift register and a gate driving device on an array substrate for eliminating the noise on the output terminal of the shift register and improving the operating stability of the shift register.

The shift register provided in an embodiment of the present disclosure comprises an input module, a pull-up module, a reset module, a first pull-down control module and a second pull-down control module and a pull-down module, wherein

the input module supplies an input signal to a pull-up node in responsive to the input signal, wherein the pull-up node serves as an output node of the input module;

the pull-up module stores the input signal and supplies a first clock signal to an output terminal in responsive to a voltage signal at the pull-up node;

the reset module supplies a negative voltage of a power supply to the pull-up node in responsive to a reset signal;

the first pull-down control module supplies the negative voltage of the power supply to a first pull-down node in response to the voltage signal at the pull-up node;

the second pull-down control module supplies the negative voltage of the power supply to a second pull-down node in response to the input signal; and

the pull-down module supplies the negative voltage of the power supply to the pull-up node in responsive to voltage signals at the first pull-down node and the second pull-down node, and supplies the negative voltage of the power supply to the output terminal in responsive to the voltage signals at the first pull-down node and the second pull-down node.

In an example, the input module comprises a first thin film transistor having a source and a gate connected to an input signal terminal and a drain serving as the output node of the input module, i.e., as the pull-up node.

In an example, the pull-up module comprises: a second thin film transistor having a drain connected to a first clock signal terminal, a gate connected to the pull-up node, and a source connected to the output terminal; and a capacitor connected between the pull-up node and the output terminal.

In an example, the reset module comprises a third thin film transistor having a drain connected to the pull-up node, a gate connected to a reset signal terminal, and a source connected to a negative voltage terminal of the power supply.

In an example, the reset module further comprises a fourth thin film transistor having a source connected to the negative voltage terminal of the power supply, a gate connected to the reset signal terminal, a drain connected to the output terminal.

In an example, the first pull-down control module comprises a fifth thin film transistor having a source connected to the negative voltage terminal of the power supply, a gate connected to the pull-up node, and a drain connected to the first pull-down node.

In an example, the first pull-down control module further comprises a sixth thin film transistor having a gate and a drain connected to the first clock signal terminal, a source connected to the first pull-down node; and a seventh thin film transistor having a drain connected to the first clock signal terminal, a gate connected to a second clock signal terminal, and a source connected to the first pull-down node.

In an example, the second pull-down control module comprises an eighth thin film transistor having a source connected to the negative voltage terminal of the power supply, a gate connected to the input signal terminal and a drain connected to the second pull-down node.

In an example, the second pull-down control module further comprises a ninth thin film transistor having a gate and a drain connected to the second clock signal terminal, and a source connected to the second pull-down node; and a tenth thin film transistor having a drain connected to the second clock signal terminal, a gate connected to the first clock signal terminal, and a source connected to the second pull-down node.

In an example, the pull-down module comprises an eleventh thin film transistor having a source connected to the negative voltage terminal of the power supply, a gate connected to the first pull-down node, and a drain connected to the pull-up node; a twelfth thin film transistor having a source connected to the negative voltage terminal of the power supply, a gate connected to the second pull-down node, and a drain connected to the pull-up node; a thirteenth thin film transistor having a source connected to the negative voltage terminal of the power supply, a gate connected to the first pull-down node, and a drain connected to the output terminal; and a fourteenth thin film transistor having a source connected to the negative voltage terminal of the power supply, a gate connected to the second pull-down node, and a drain connected to the output terminal.

Hereinafter a detailed description will be given to the present disclosure in combination with the accompanying drawings and the specific embodiments.

### Embodiment 1

Referring to FIG. 2, a shift register provided in the embodiment 1 of the present disclosure comprises: an input module 101, a pull-up module 102, a reset module 103, a first pull-down control module 1041 and a second pull-down control module 1051 and a pull-down module 106.

The input module 101 supplies an input signal at an input signal terminal INPUT to a pull-up node PU in responsive to the input signal, wherein the pull-up node serves as an output node of the input module. The input module 101 may comprise a first thin film transistor M1 having a source and a gate connected to the input signal terminal INPUT and a drain serving as the output node of the input module, i.e., as the pull-up node PU.

The pull-up module 102 stores the input signal and supplies a first clock signal at a first clock signal terminal CLK to an output terminal OUTPUT in responsive to a voltage signal at the pull-up node PU. The pull-up module 102 may comprise: a second thin film transistor M2 having a drain connected to the first clock signal terminal CLK, a gate connected to the pull-up node PU, and a source connected to the output terminal OUTPUT; and a capacitor C connected between the pull-up node PU and the output terminal OUTPUT.

The reset module 103 supplies a voltage at a negative voltage terminal VSS of a power supply to the pull-up node PU in responsive to a reset signal at a reset signal terminal RESET. The reset module 103 may comprise a third thin film transistor M3 having a drain connected to the pull-up node PU, a gate connected to the reset signal terminal RESET, and a source connected to the negative voltage terminal VSS of the power supply.

A first pull-down control module 1041 supplies the voltage at the negative voltage terminal VSS of the power supply to a first pull-down node PD1 in response to the voltage signal at the pull-up node PU. The pull-down control module 1041 may comprise a fifth thin film transistor M5 having a source connected to the negative voltage terminal VSS of the power supply, a gate connected to the pull-up node PU, and a drain connected to the first pull-down node PD1.

A second pull-down control module 1051 supplies the voltage at the negative voltage terminal VSS of the power supply to a second pull-down node PD2 in response to the input signal. The second pull-down control module 1051 may comprise an eighth thin film transistor having a source connected to the negative voltage terminal VSS of the power supply, a gate connected to the input signal terminal INPUT and a drain connected to the second pull-down node PD2.

The pull-down module 106 supplies the negative voltage of the power supply to the pull-up node PU in responsive to voltage signals at the first pull-down node PD1 and at the second pull-down node PD2, and supplies the negative voltage of the power supply to the output terminal in responsive to voltage signals at the first pull-down node PD1 and at the second pull-down node PD2. The pull-down module 106 may comprise an eleventh thin film transistor M11 having a source connected to the negative voltage terminal VSS of the power supply, a gate connected to the first pull-down node PD1, and a drain connected to the pull-up node PU; a twelfth thin film transistor M12 having a source connected to the negative voltage terminal VSS of the power supply, a gate connected to the second pull-down node PD2, and a drain connected to the pull-up node PU; a thirteenth thin film transistor M13 having a source connected to the negative voltage terminal VSS of the power supply, a gate connected to the first pull-down node PD1, a drain connected to the output terminal OUTPUT; and a fourteenth thin film transistor M14 having a source connected to the negative voltage terminal VSS of the power supply, a gate connected to the second pull-down node PD2, a drain connected to the output terminal OUTPUT.

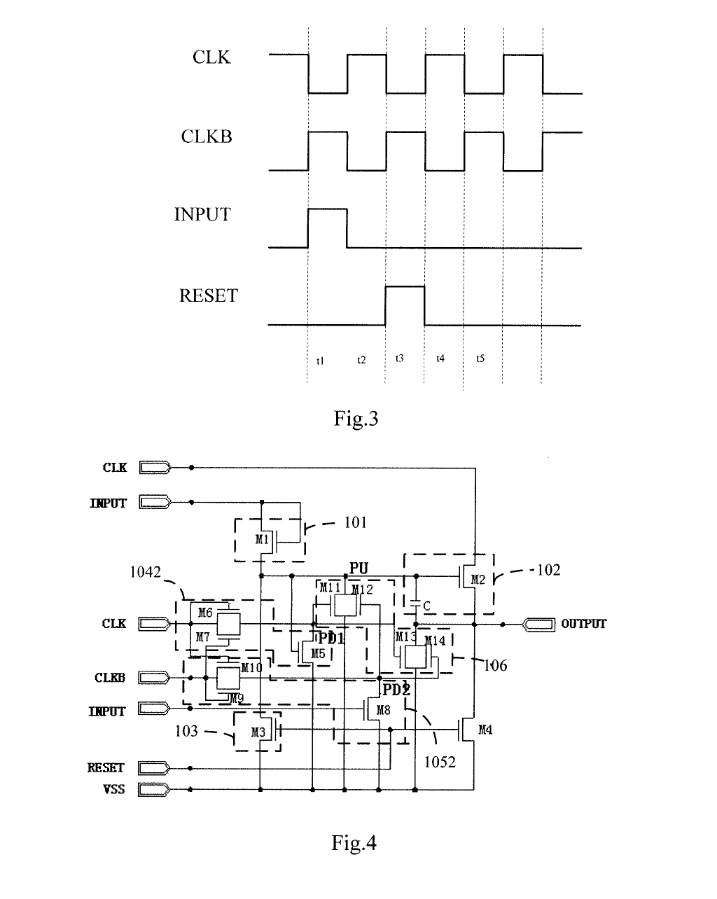

With reference to the timing diagram of control signals shown in FIG. 3, a driving method for the shift register provided in the embodiment 1 of the present disclosure comprises:

a first phase t1, when an input signal at the input signal terminal INPUT is at a high level, a first clock signal at the first clock signal terminal CLK is at a low level, a second clock signal at the second clock signal terminal CLKB is at a high level and a reset signal at the reset signal terminal RESET is at a low level, the first thin film transistor M1 and the eighth thin film transistor M8 are turned on simultaneously, and a high level voltage is imported to the node PU, and a low level voltage is imported to the node PD2, thus the twelfth thin film transistor M12 and the fourteenth thin film transistor M14 are turned off; the node PD1 is at the voltage of the first clock signal, i.e., at a low level, and thus the eleventh thin film transistor Mil and the thirteenth thin film transistor M13 are turned off; the voltage imported by the node PU is at a high level, and the second thin film transistor M2 is turned on, a low level voltage of the first clock signal is output from the output terminal OUTPUT;

a second phase t2, when the input signal at the input signal terminal INPUT is at a low level, the first clock signal at the first clock signal terminal CLK is at a high level, the second clock signal at the second clock signal terminal CLKB is at a low level and the reset signal at the reset signal terminal RESET is at a low level, the node PU remains a high level due to the effect of the capacitor C, the second thin film transistor M2 is turned on, and the potential at the node PU is further pulled up by the coupling effect of the second thin film transistor M2; meanwhile the nodes PD1 and PD2 are at a low level, and the thin film transistors M11 and M12 are turned off, ensuring that the high level voltage of the first clock signal is output to the output terminal OUTPUT via M2 without leakage at the node PU, and M13 and M14 are turned off so as to ensure that a high level voltage is output without leakage at the output terminal;

a third phase t3, when the input signal at the input signal terminal INPUT is at a low level, the first clock signal at the first clock signal terminal CLK is at a low level, the second clock signal at the second clock signal terminal CLKB is at a high level and the reset signal at the reset signal terminal RESET is at a high level, the potential at the node PD1 and that at the node PD2 are at a low level and at a high level respectively, the third thin film transistor M3, the twelfth thin film transistor M12 and the fourteenth thin film transistor M14 are turned on; a low level voltage is imported to the node PU and the output terminal OUTPUT respectively to pull down the levels at the node PU and the output terminal OUTPUT, thus a low level voltage being output from the output terminal;

a fourth phase t4, when the input signal at the input signal terminal INPUT is at a low level, the first clock signal at the first clock signal terminal CLK is at a high level, the second clock signal at the second clock signal terminal CLKB is at a low level and the reset signal at the reset signal terminal RESET is at a low level, the potential at the node PD1 and that at the node PD2 are at a high level and a low level respectively, making the eleventh thin film transistor M11 and the thirteenth thin film transistor M13 be turned on, and a low level voltage is imported to the node PU and the output terminal OUTPUT respectively so that the output terminal outputs a low level voltage;

a fifth phase t5, when the input signal at the input signal terminal INPUT is at a low level, the first clock signal at the first clock signal terminal CLK is at a low level, the second clock signal at the second clock signal terminal CLKB is at a high level and the reset signal at the reset signal terminal RESET is at a low level, the potential at the node PD1 and that at the node PD2 are at a low level and a high level respectively, making the twelfth thin film transistor M12 and the fourteenth thin film transistor M14 be turned on, and a low level voltage is imported to the node PU and the output terminal OUTPUT respectively so that the output terminal outputs a low level voltage;

After the fifth phase t5, the operations from the fourth phase t4 to the fifth phase t5 are repeated, until the timing sequence of the first phase t1, the second phase t2 and the third phase t3 in sequence occurs and the operations of the first phase t1, the second phase t2 and the third phase t3 are performed again, that is, the node PU and the output terminal OUTPUT are discharged by the eleventh and thirteenth thin film transistors M11 and M13 as well as the twelfth and fourteen thin film transistors M12 and M14 alternately, ensuring that the output terminal OUTPUT and the node PU of the shift register remain at a low level all the time except the period in which the shift register outputs a high level voltage, and thus the function of removing the noise and prolonging the lifespan of the shift register is realized.

It should be noted that the above embodiment of the present disclosure takes the case in which the shift register is applied to a structure in which scanning is performed in one direction as an example, wherein the supply voltage at the negative voltage terminal VSS of the power supply is at a low level, and all the thin film transistors are N type thin film transistors, and thus all the thin film transistors are turned on when the gates thereof are supplied with high level voltages, and are turned off when the gates thereof are supplied with low level voltages. Other embodiments have the same situation, and the details are omitted.

### Embodiment 2

Referring to FIG. 4, a shift register provided in the embodiment 2 of the present disclosure comprises: an input module 101, a pull-up module 102, a reset module 103, a first pull-down control module 1042 and a second pull-down control module 1052 and a pull-down module 106.

The input module 101 supplies an input signal at an input signal terminal INPUT to a pull-up node PU in responsive to the input signal, wherein the pull-up node serves as an output node of the input module. The input module 101 may comprise a first thin film transistor M1 having a source and a gate connected to the input signal terminal INPUT and a drain serving as the output node of the input module, i.e., as the pull-up node PU.

The pull-up module 102 stores the input signal and supplies a first clock signal at a first clock signal terminal CLK to an output terminal OUTPUT in responsive to a voltage signal at the pull-up node PU. The pull-up module 102 may comprise: a second thin film transistor M2 having a drain connected to the first clock signal terminal CLK, a gate connected to the pull-up node PU, and a source connected to the output terminal OUTPUT; and a capacitor C connected between the pull-up node PU and the output terminal OUTPUT.

The reset module 103 supplies a voltage at a negative voltage terminal VSS of a power supply to the pull-up node PU in responsive to a reset signal at a reset signal terminal RESET. The reset module 103 may comprise: a third thin film transistor M3 having a drain connected to the pull-up node PU, a gate connected to the reset signal terminal RESET, and a source connected to the negative voltage terminal VSS of the power supply; a fourth thin film transistor M4 having a source connected to the negative voltage terminal VSS of the power supply, a gate connected to the reset signal terminal RESET, and a drain connected to the output terminal OUTPUT.

A first pull-down control module 1042 supplies a voltage at the negative voltage terminal VSS of the power supply to a first pull-down node PD1 in response to a voltage signal at the pull-up node PU. The first pull-down control module 1042 may comprise a fifth thin film transistor M5 having a source connected to the negative voltage terminal VSS of the power supply, a gate connected to the pull-up node PU, and a drain connected to the first pull-down node PD1; a sixth thin film transistor M6 having a gate and a drain connected to the first clock signal terminal CLK, and a source connected to the first pull-down node PD1; a seventh thin film transistor M7 having a drain connected to the first clock signal terminal CLK, a gate connected to the second clock signal terminal CLKB, and a source connected to the first pull-down node PD1.

A second pull-down control module 1052 supplies the voltage at the negative voltage terminal VSS of the power supply to a second pull-down node PD2 in response to the input signal. The second pull-down control module 1052 may comprise an eighth thin film transistor having a source connected to the negative voltage terminal VSS of the power supply, a gate connected to the input signal terminal INPUT and a drain connected to the second pull-down node PD2; a ninth thin film transistor M9 having a gate and a drain connected to the second clock signal terminal CLKB, a source connected to the second pull-down node PD2; and a tenth thin film transistor M10 having a drain connected to the second clock signal terminal CLKB, a gate connected to the first clock signal terminal CLK, and a source connected to the second pull-down node PD2.

The pull-down module 106 supplies the voltage at the negative voltage terminal VSS of the power supply to the pull-up node PU in responsive to voltage signals at the first pull-down node PD1 and at the second pull-down node PD2, and supplies the voltage at the negative voltage terminal VSS of the power supply to the output terminal in responsive to voltage signals at the first pull-down node PD1 and at the second pull-down node PD2. The pull-down module 106 may comprise an eleventh thin film transistor M11 having a source connected to the negative voltage terminal VSS of the power supply, a gate connected to the first pull-down node PD1, and a drain connected to the pull-up node PU; a twelfth thin film transistor M12 having a source connected to the negative voltage terminal VSS of the power supply, a gate connected to the second pull-down node PD2, and a drain connected to the pull-up node PU; a thirteenth thin film transistor M13 having a source connected to the negative voltage terminal VSS of the power supply, a gate connected to the first pull-down node PD1, a drain connected to the output terminal OUTPUT; and a fourteenth thin film transistor M14 having a source connected to the negative voltage terminal VSS of the power supply, a gate connected to the second pull-down node PD2, a drain connected to the output terminal OUTPUT.

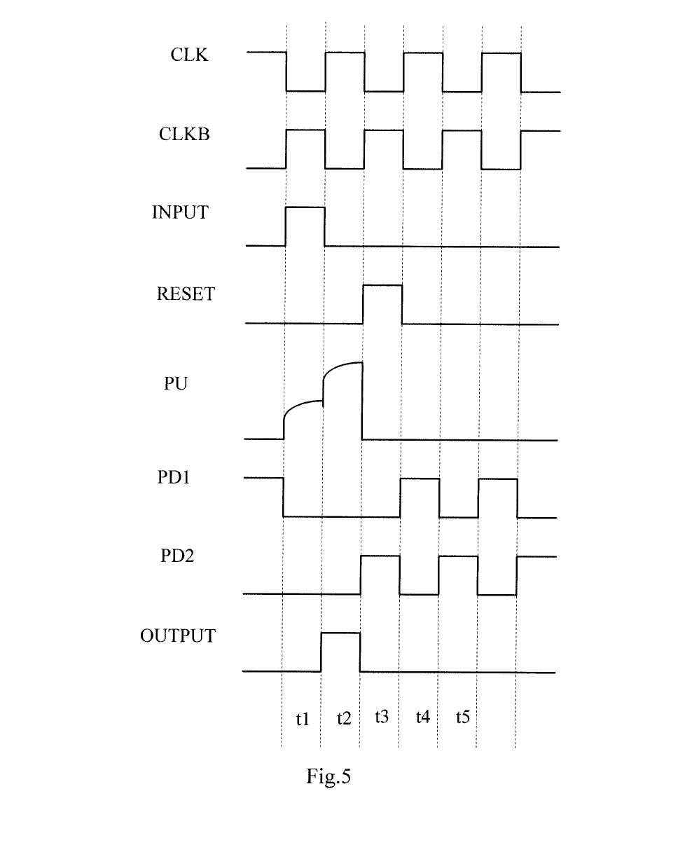

With reference to the timing diagram of control signals shown in FIG. 5, a driving method for the shift register provided in the embodiment 2 of the present disclosure comprises:

a first phase t1, when an input signal at the input signal terminal INPUT is at a high level, a first clock signal at the first clock signal terminal CLK is at a low level, a second clock signal at the second clock signal terminal CLKB is at a high level and a reset signal at the reset signal terminal RESET is at a low level, the first thin film transistor M1 and the eighth thin film transistor M8 are turned on simultaneously, and a high level voltage is imported to the node PU; by adjusting the ratio of the size of the eighth thin film transistor M8 to that of the ninth thin film transistor M9, even though the second clock signal at a high level is output to the node PD2 via the ninth thin film transistor M9, the high level voltage generated at the node PD2 is released to VSS via the turning-on of the eighth thin film transistor M8, ensuring the node PD2 to be at a low level, and thus the twelfth thin film transistor M12 and the fourteenth thin film transistor M14 are turned off; in addition, the seventh thin film transistor M7 is turned on, the node PD1 is at a low level, the eleventh thin film transistor M11 and the thirteenth thin film transistor M13 are turned off, and the duty ratios of the eleventh and thirteenth thin film transistors M11 an M13 can be reduced and the lifespan thereof can be prolonged; the input signal voltage imported by the node PU is at a high level, and the second thin film transistor M2 is turned on, the first clock signal at the first clock signal terminal CLK at a low level is output from the output terminal OUTPUT;

a second phase t2, when the input signal at the input signal terminal INPUT is at a low level, the first clock signal at the first clock signal terminal CLK is at a high level, the second clock signal at the second clock signal terminal CLKB is at a low level and the reset signal at the reset signal terminal RESET is at a low level, the node PU remains a high level, and the second thin film transistor M2 is turned on; by adjusting the ratio of the size of fifth thin film transistor M5 to that of the sixth thin film transistor M6, so that when the node PU is at a high level, even though the first clock signal of the first clock signal terminal CLK at a high level is output via the sixth thin film transistor M6, the high level voltage generated at the node PD1 is released to VSS via the turning-on of the fifth thin film transistor M5, ensuring the node PD1 to be at a low level, and thus the eleventh thin film transistor M11 and the thirteenth thin film transistor M13 are turned off; the tenth thin film transistor M10 is turned on, the node PD2 is at a low level, and the twelfth thin film transistor M12 and the fourteenth thin film transistor M14 are turned off, which can decrease the duty ratios of the twelfth and fourteenth thin film transistors M12 and M14 and prolong their lifespan; the potential at the node PU is further pulled up by the coupling effect of the second thin film transistor M2; meanwhile the first clock signal CLK at the high level during this phase is output to the output terminal OUTPUT so that a high level voltage is output from the output terminal OUTPUT;

a third phase t3, when the input signal at the input signal terminal INPUT is at a low level, the first clock signal at the first clock signal terminal CLK is at a low level, the second clock signal at the second clock signal terminal CLKB is at a high level and the reset signal at the reset signal terminal RESET is at a high level, the potential at the node PD1 is at a low level due to the turning-on of the seventh thin film transistor M7, and the node PD2 is at a high level due to the turning-on of the ninth thin film transistor M9, and thus the twelfth thin film transistor M12 and the fourteenth thin film transistor M14 are turned on, and a low level voltage is imported to the node PU and the output terminal OUTPUT respectively, and at the same time the reset signal is at a high level to turn on the third and fourth thin film transistors M3 and M4, and the discharging of the node PU is expedited due to the turning-on of the third thin film transistor M3, and the importing of the low level to the output terminal OUTPUT is expedited due to the turning-on of the fourth thin film transistor M4 so that a low level voltage is output from the output terminal OUTPUT;

a fourth phase t4, when the input signal at the input signal terminal INPUT is at a low level, the first clock signal at the first clock signal terminal CLK is at a high level, the second clock signal at the second clock signal terminal CLKB is at a low level and the reset signal at the reset signal terminal RESET is at a low level, the potential at the node PD1 is at a high level due to the turning-on of the sixth thin film transistor M6, the potential at the node PD2 is at a low level due to the turning-on of the tenth thin film transistor M10, making the eleventh thin film transistor M11 and the thirteenth thin film transistor M13 be turned on, and a low level voltage is imported to the node PU and the output terminal OUTPUT respectively so that a low level voltage is output from the output terminal OUTPUT;

a fifth phase t5, when the input signal at the input signal terminal INPUT is at a low level, the first clock signal at the first clock signal terminal CLK is at a low level, the second clock signal at the second clock signal terminal CLKB is at a high level and the reset signal at the reset signal terminal RESET is at a low level, the potential at the node PD1 and that at the node PD2 are at a low level and a high level respectively, making the twelfth thin film transistor M12 and the fourteenth thin film transistor M14 be turned on, and a low level voltage is imported to the node PU and the output terminal OUTPUT respectively so that a low level voltage is output from the output terminal OUTPUT;

After the fifth phase t5, the operations from the fourth phase t4 to the fifth phase t5 are repeated, until the timing sequence of the first phase t1, the second phase t2 and the third phase t3 in sequence occurs and the operations of the first phase t1, the second phase t2 and the third phase t3 are performed again, that is, the node PU and the output terminal OUTPUT are discharged by the eleventh thin film transistor M11 and the thirteenth thin film transistor M13 as well as the twelfth thin film transistor M12 and the fourteenth thin film transistor M14 alternating, ensuring that the output terminal OUTPUT and the node PU of the shift register remain at a low level all the time except the period in which the shift register outputs a high level voltage, and thus the function of removing the noise and prolonging the lifespan of the shift register is realized.

FIG. 5 shows the timing diagram of the individual control signals and the potentials at the nodes PU, PD1 and PD2 when the shift register provided in the embodiment 2 of the present disclosure is in operation.

It should be noted that in the embodiment 2 of the present disclosure, it is unnecessary for the combination of the fourth thin film transistor M4, the sixth thin film transistor M6 and the seventh thin film transistor M7 and the combination of the fourth thin film transistor M4, the ninth thin film transistor M9 and the tenth thin film transistor M10 to coexist in the shift register, and any combination thereof can achieve the function of the embodiment of the present disclosure.

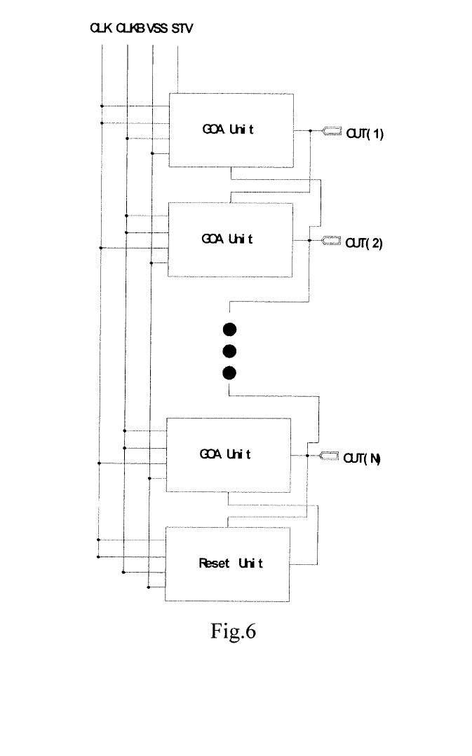

An embodiment of the present disclosure provides a gate driving device on array substrate, referring to the structure diagram of the gate driving device on array substrate in concatenation shown in FIG. 6, and the shift register provided in the embodiment 2 of the present disclosure is taken as an example of the shift register of the basic unit of the structure in concatenation.

Supposing that the whole gate driving circuit has N-stage driving units in total, N representing the number of the gate lines, each stage of driving units is formed for example by the shift register provided in the embodiment 2 of the present disclosure, wherein the signal input terminal INPUT of the first stage driving unit is supplied with an input signal STV, the reset terminal RESET thereof is supplied with a reset signal by the output terminal OUTPUT (OUT(2)) of the second stage driving unit, the signal input terminal INPUT of the N^{th} stage driving unit is supplied with an input signal by the output terminal OUTPUT of the (N−1)^{th} stage driving unit, the reset terminal RESET thereof is supplied with a reset signal by a reset unit, the n^{th} stage driving unit (1<n<N) is supplied with an input signal by the output terminal of the (n−1)^{th} stage driving unit, and the reset signal of the n^{th} stage driving unit is supplied by the output terminal of the (n+1)^{th} stage driving unit.

In summary, in the shift register and the gate driving device on array substrate provided in the embodiments of the present disclosure, the noise at the output terminal of the shift register can be eliminated, the operating stability can be improved, and the lifespan of shift register can be prolonged. When the shift register does not output a scanning pulse, the output terminal OUTPUT and the pull-up node PU are discharged alternately by the clock signal CLK and CLKB having opposite phases, so that the output terminal OUTPUT and the node PU of each stage of shift registers remain at a low level all the time except the period in which the shift register outputs a scanning pulse, and thus the function of eliminating the noise at the output terminal and prolonging the lifespan of the shift register can be implemented.

It should be appreciated for those skilled in the art that many modifications, variations or equivalences can be made in the embodiments of the present disclosure without departing from the spirit and the scope of the present disclosure. Thus, provided that all the modifications and variations belong to the scope as claimed in the present disclosure and the equivalent technical means, such modifications and variations fall into the protection scope of the present disclosure as defined by the appended claims.

What is claimed is:

1. A shift register comprising an input module, a pull-up module, a reset module, a first pull-down control module and a second pull-down control module and a pull-down module, wherein
the input module supplies an input signal at an input signal terminal to a pull-up node in responsive to the input signal, wherein the pull-up node serves as an output node of the input module;
the pull-up module stores the input signal and supplies a first clock signal at a first clock signal terminal to the output terminal in responsive to a voltage signal at the pull-up node;
the reset module supplies a negative voltage at a negative voltage terminal of a power supply to the pull-up node in responsive to a reset signal at a reset signal terminal;
the first pull-down control module supplies the negative voltage of the power supply to a first pull-down node in response to a voltage signal at the pull-up node;
the second pull-down control module supplies the negative voltage of the power supply to a second pull-down node in response to the input signal; and
the pull-down module supplies the negative voltage of the power supply to the pull-up node in responsive to voltage signals at the first pull-down node and the second pull-down node, and supplies the negative voltage of the power supply to the output terminal in responsive to the voltage signals at the first pull-down node and the second pull-down node.

2. The shift register of claim 1, wherein the input module comprises:
a first thin film transistor having a source and a gate connected to the input signal terminal and a drain serving as the output node of the input module, i.e., as the pull-up node.

3. The shift register of claim 1, wherein the pull-up module comprises:
a second thin film transistor having a drain connected to the first clock signal terminal, a gate connected to the pull-up node, and a source connected to the output terminal; and
a capacitor connected between the pull-up node and the output terminal.

4. The shift register of claim 1, wherein the reset module comprises:
a third thin film transistor having a drain connected to the pull-up node, a gate connected to the reset signal terminal, and a source connected to the negative voltage terminal of the power supply.

5. The shift register of claim 4, wherein the reset module further comprises:
a fourth thin film transistor having a source connected to the negative voltage terminal of the power supply, a gate connected to the reset signal terminal, a drain connected to the output terminal.

6. The shift register of claim 1, wherein the first pull-down control module comprises:
a fifth thin film transistor having a source connected to the negative voltage terminal of the power supply, a gate connected to the pull-up node, and a drain connected to the first pull-down node.

7. The shift register of claim 6, wherein the first pull-down control module further comprises:
a sixth thin film transistor having a gate and a drain connected to the first clock signal terminal, a source connected to the first pull-down node;
a seventh thin film transistor having a drain connected to the first clock signal terminal, a gate connected to a second clock signal terminal, and a source connected to the first pull-down node.

8. The shift register of claim 1, wherein the second pull-down control module comprises:
an eighth thin film transistor having a source connected to the negative voltage terminal of the power supply, a gate connected to the input signal terminal, and a drain connected to the second pull-down node.

9. The shift register of claim 8, wherein the second pull-down control module further comprises:
a ninth thin film transistor having a gate and a drain connected to the second clock signal terminal, and a source connected to the second pull-down node; and
a tenth thin film transistor having a drain connected to the second clock signal terminal, a gate connected to the first clock signal terminal, and a source connected to the second pull-down node.

10. The shift register of claim 1, wherein the pull-down module comprises:
an eleventh thin film transistor having a source connected to the negative voltage terminal of the power supply, a gate connected to the first pull-down node, and a drain connected to the pull-up node;
a twelfth thin film transistor having a source connected to the negative voltage terminal of the power supply, a gate connected to the second pull-down node, and a drain connected to the pull-up node;
a thirteenth thin film transistor having a source connected to the negative voltage terminal of the power supply, a gate connected to the first pull-down node, a drain connected to the output terminal; and
a fourteenth thin film transistor having a source connected to the negative voltage terminal of the power supply, a gate connected to the second pull-down node, a drain connected to the output terminal.

11. A gate driving device on array substrate comprising a plurality of shift registers of claim 1 connected in concatenation.
